(19) United States
(12) Patent Application Publication
(10) Pub. No.: US 2021/0359190 A1
(43) Pub. Date: Nov. 18, 2021

(54) THERMOELECTRIC CONVERSION SUBSTRATE AND THERMOELECTRIC CONVERSION MODULE

(71) Applicant: PANASONIC INTELLECTUAL PROPERTY MANAGEMENT CO., LTD., Osaka (JP)

(72) Inventors: Satoshi Maeshima, Kyoto (JP); Takashi Seda, Kyoto (JP)

(21) Appl. No.: 17/388,996

(22) Filed: Jul. 29, 2021

Related U.S. Application Data
(63) Continuation of application No. PCT/JP2020/005464, filed on Feb. 13, 2020.
(60) Provisional application No. 62/806,038, filed on Feb. 15, 2019.

(51) Int. Cl. H01L 35/32; H01L 35/08; H01L 23/38; H01L 23/36

(52) U.S. Cl. CPC H01L 35/32; H01L 23/36; H01L 23/38; H01L 35/08

(57) ABSTRACT

A thermoelectric conversion substrate includes: an insulating substrate including a first surface on one side in a thickness direction of the insulating substrate and a second surface on an opposite side; a plurality of thermoelectric conversion units, each including a first thermoelectric member, a second thermoelectric member, and a first electrode that electrically connects the first thermoelectric member and the second thermoelectric member; and a second electrode. The insulating substrate includes at least one core insulating layer. The second electrode electrically connects the first thermoelectric member of one of the thermoelectric conversion units and the second thermoelectric member of another of the thermoelectric conversion units. The thermoelectric conversion units are electrically connected in series in a manner that the first thermoelectric member and the second thermoelectric member are alternately arranged. A stress relaxation portion is disposed between the first thermoelectric member and the second thermoelectric member.

### CROSS REFERENCE TO RELATED APPLICATIONS

This application is a U.S. continuation application of PCT International Patent Application Number PCT/JP2020/005464 filed on Feb. 13, 2020, claiming the benefit of priority of U.S. Provisional Patent Application No. 62/806,038 filed on Feb. 15, 2019, the entire contents of which are hereby incorporated by reference.

### BACKGROUND

### 1. Technical Field

The present disclosure generally relates to a thermoelectric conversion substrate and a thermoelectric conversion module, and more particularly to a thermoelectric conversion substrate and a thermoelectric conversion module utilizing Peltier devices.

### 2. Description of the Related Art

Conventional thermoelectric conversion substrates include, for example, a thermoelectric conversion substrate disclosed in WO2017/208950. Such thermoelectric conversion substrate includes an insulating substrate and thermoelectric conversion units. The insulating substrate includes a first surface and a second surface at both ends of the insulating substrate in a thickness direction of the insulating substrate. The thermoelectric conversion units are incorporated in the insulating substrate. Each of the thermoelectric conversion units includes a first thermoelectric member, a second thermoelectric member, and a first electrode disposed on the first surface of the insulating substrate. The first thermoelectric member includes a first tubular member having insulation property and a first semiconductor filled in the first tubular member. The second thermoelectric member includes a second tubular member having insulation property and a second semiconductor filled in the second tubular member. The carriers of the second semiconductor are different from the carriers of the first semiconductor. The first electrode electrically connects the first semiconductor of the first thermoelectric member and the second semiconductor of the second thermoelectric member. The thermoelectric conversion substrate further includes a second electrode disposed on the second surface of the insulating substrate. The second electrode electrically connects the first semiconductor of the first thermoelectric member in one of the thermoelectric conversion units and the second semiconductor of the second thermoelectric member in another of the thermoelectric conversion units. The thermoelectric conversion units are electrically connected in series in a manner that the first semiconductor and the second semiconductor are alternately arranged. With the foregoing configuration, the thermoelectric conversion substrate achieves the Peltier effect or the Seebeck effect.

### SUMMARY

In the thermoelectric conversion substrate disclosed in WO2017/208950, heat transferred in the insulating substrate affects the function, life, etc. of the thermoelectric conversion units or an electronic device to be subjected to thermoelectric conversion. For example, heat, etc. generated from the electronic device or generated in the manufacturing process causes a thermal expansion difference inside of the insulating substrate, as a result of which stress is generated. The conventional technology thus has a problem that the thermoelectric conversion units are prone to breakage under such stress.

In view of the foregoing problem, the present disclosure provides a thermoelectric conversion substrate and so forth that reduce the breakage of a thermoelectric conversion unit.

The thermoelectric conversion substrate according to an aspect of the present disclosure includes: an insulating substrate including a first surface on one side in a thickness direction of the insulating substrate and a second surface on an opposite side; a plurality of thermoelectric conversion units, each including a first thermoelectric member, a second thermoelectric member, and a first electrode that is disposed on the first surface and electrically connects the first thermoelectric member and the second thermoelectric member; and a second electrode disposed on the second surface. In the thermoelectric conversion substrate, the insulating substrate includes at least one core insulating layer, the first thermoelectric member and the second thermoelectric member are incorporated in the at least one core insulating layer, the second electrode electrically connects the first thermoelectric member of one of the plurality of thermoelectric conversion units and the second thermoelectric member of another of the plurality of thermoelectric conversion units, the plurality of thermoelectric conversion units are electrically connected in series in a manner that the first thermoelectric member and the second thermoelectric member are alternately arranged, and a stress relaxation portion is disposed between the first thermoelectric member and the second thermoelectric member.

The thermoelectric conversion module according to an aspect of the present disclosure includes: the foregoing thermoelectric conversion substrate; an insulating film disposed on at least one of the first surface or the second surface of the insulating substrate of the thermoelectric conversion substrate; and an electronic component disposed on the thermoelectric conversion substrate via the insulating film.

The present disclosure provides a thermoelectric conversion substrate and so forth that reduce the breakage of a thermoelectric conversion unit.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a schematic cross-sectional view of an exemplary thermoelectric conversion module according to Embodiment 1;

FIG. 2A is a schematic perspective view of an exemplary first thermoelectric member according to Embodiment 1;

FIG. 2B is a schematic perspective view of an exemplary second thermoelectric member according to Embodiment 1;

FIG. 3A is a schematic cross-sectional view of an exemplary thermoelectric conversion substrate according to Example 1 of Embodiment 1;

FIG. 3B is a schematic cross-sectional view of an exemplary thermoelectric conversion substrate according to Example 1 of Embodiment 1;

FIG. 3C is a schematic cross-sectional view of another exemplary thermoelectric conversion substrate according to Example 1 of Embodiment 1;

FIG. 3D is a schematic cross-sectional view of an exemplary thermoelectric conversion substrate according to Example 2 of Embodiment 1;

FIG. 4A is a schematic cross-sectional view of an exemplary thermoelectric conversion module according to Example 1 of Embodiment 2;

FIG. 4B is a schematic cross-sectional view of an exemplary thermoelectric conversion module according to Example 2 of Embodiment 2; and

FIG. 4C is a schematic cross-sectional view of an exemplary thermoelectric conversion module according to Example 3 of Embodiment 2.

### DETAILED DESCRIPTION OF THE EMBODIMENTS

The following specifically describes the thermoelectric conversion substrate and others according to the embodiments of the present disclosure with reference to the drawings. Note that the following embodiments show a comprehensive or specific illustration of the present disclosure. The numerical values, shapes, materials, structural components, the arrangement and connection of the structural components, etc. shown in the following embodiments are mere examples, and thus are not intended to limit the present disclosure.

In the following embodiments, the terms “upward (above)” and “downward (below)” do not indicate an upward direction (vertically upward) and a downward direction (vertically downward), respectively, from the standpoint of an absolute space recognition. Also, the terms “upward (above)” and “downward (below)” are applicable not only to the case where a structural component is present between two structural components that are disposed spaced apart from each other, but also to the case where the two structural components are disposed in intimate contact with each other.

In the present specification and the accompanying drawings, the x axis, the y axis, and the z axis indicate three axes in the three-dimensional orthogonal coordinate system. In the following embodiments, a first surface of an insulating substrate is parallel to the xy plane, and the direction perpendicular to the xy plane is defined as the z axis direction. Also in the following embodiments, the positive direction of the z axis is also described as upward (above), and the negative direction of the z axis is also described as downward (below).

Also, in the present specification, “a plan view” means a view of the thermoelectric conversion substrate, and so forth seen from the positive direction of the z axis. Also, a cross-sectional view is a view that shows only a surface visible on a cross-section.

In the present specification, nickel is also referred to as Ni, titanium as Ti, tin as Sn, gold as Au, silver as Ag, copper as Cu, and aluminum as Al.

### Embodiment 1

Before explaining Embodiment 1 according to the present disclosure, the problem of the conventional technology will be briefly described.

In the thermoelectric conversion substrate disclosed in WO2017/208950, heat transferred in the insulating substrate affects the function, life, etc. of the thermoelectric conversion units or an electronic device to be subjected to thermoelectric conversion. For example, heat, etc. generated from the electronic device or generated in the manufacturing process causes a thermal expansion difference inside of the insulating substrate, as a result of which stress is generated. The conventional technology thus has a problem that the thermoelectric conversion units are prone to breakage under such stress.

The present disclosure, which has been conceived in view of the foregoing problem, provides a thermoelectric conversion substrate and a thermoelectric conversion module that reduce the breakage of a thermoelectric conversion unit.

The following describes Embodiment 1 according to the present disclosure.

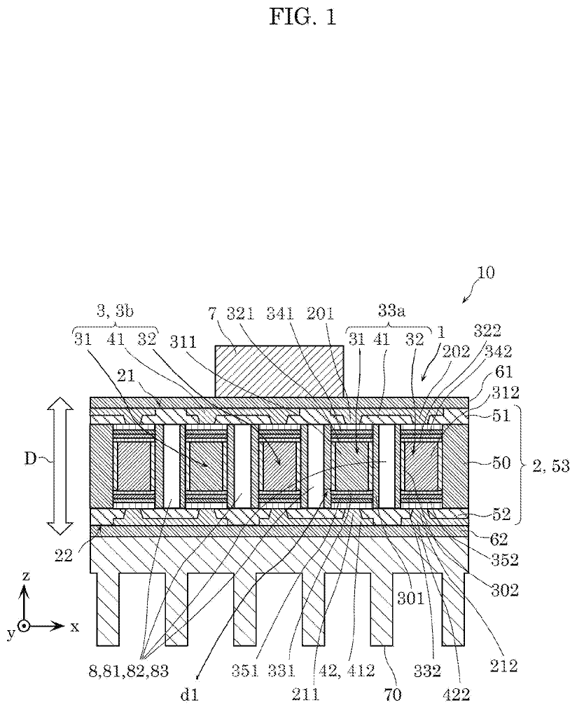

FIG. 1 shows an example of thermoelectric conversion substrate 1 and thermoelectric conversion module 10. FIG. 1 is a schematic cross-sectional view of an example of thermoelectric conversion module 10 according to Embodiment 1.

Thermoelectric conversion module 10 includes thermoelectric conversion substrate 1, insulating film 61, electronic component 7, thermally conductive layer 62, and heatsink 70. Thermoelectric conversion substrate 1 will be described first.

Thermoelectric conversion substrate 1 includes insulating substrate 2, a plurality of thermoelectric conversion units 3, and second electrode 42. Thermoelectric conversion substrate 1 also includes stress relaxation portions 8. For identification purposes, a plurality of thermoelectric conversion units 3 are also described distinctively as thermoelectric conversion unit 3a and thermoelectric conversion unit 3b.

Insulating substrate 2 includes first surface 21 on one side in the thickness direction of insulating substrate 2 and second surface 22 on the opposite side. The thickness direction is indicated by the double-headed arrow D in FIG. 1. First surface 21 and second surface 22 serve as the both surfaces of insulating substrate 2. Either surface may be the top surface or the back surface. In the present embodiment, first surface 21 is located at the positive side of the z axis and second surface 22 is located at the negative side of the z axis. Insulating substrate 2 may be any substrate having insulation property. Insulating substrate 2 is, for example, a substrate formed by impregnating a reinforcing material with a thermosetting resin composition and curing the resultant.

Specific examples of insulating substrate 2 include a glass epoxy substrate. A glass epoxy substrate is a substrate formed by impregnating a glass fiber cloth, which is a reinforcing material, with a thermosetting resin composition containing epoxy resin, and curing the resultant. The thermosetting resin composition may contain a filler.

Insulating substrate 2 includes at least one core insulating layer 50. As shown in FIG. 1, insulating substrate 2 may include core insulating layer 50, first insulating layer 51, and second insulating layer 52. In this case, insulating substrate 2 is laminate 53. With insulating substrate 2 including a plurality of layers, it is possible to change the heat conductivity of each of the layers (core insulating layer 50, first insulating layer 51, and second insulating layer 52) depending on the usage of thermoelectric conversion substrate 1. Each of the layers may be any layer having insulation property. Each of the layers is, for example, a layer formed by impregnating a reinforcing material with a thermosetting resin composition, and curing the resultant. The thermosetting resin composition may contain a filler. With the thermosetting resin composition containing a filler, it is possible to change the heat conductivity of each of the layers. Specific examples of the filler include alumina, silica, magnesium hydroxide, and aluminum hydroxide.

Core insulating layer 50 incorporates first thermoelectric members 31 and second thermoelectric members 32 included in thermoelectric conversion units 3 (first thermoelectric members 31 and second thermoelectric members 32 will be described later). The thickness of core insulating layer 50 (the length in the z axis direction) is equal to or greater than the lengths of first thermoelectric members 31 and second thermoelectric members 32 (the lengths in the z axis direction). Core insulating layer 50 is located between first insulating layer 51 and second insulating layer 52. Examples of the heat conductivity of core insulating layer 50 include, but not limited to, the heat conductivity between 0.5 W/m·K and 0.8 W/m·K, inclusive.

First insulating layer 51 includes neither first thermoelectric member 31 nor second thermoelectric member 32. The thickness of first insulating layer 51 is 200 μm or less. First insulating layer 51 is located at the side of first surface 21 of insulating substrate 2. Examples of the heat conductivity of first insulating layer 51 include, but not limited to, the heat conductivity between 1.1 W/m·K and 1.6 W/m·K, inclusive.

Second insulating layer 52 includes neither first thermoelectric member 31 nor second thermoelectric member 32. The thickness of second insulating layer 52 is 200 μm or less. Second insulating layer 52 is located at the side of second surface 22 of insulating substrate 2. Examples of the heat conductivity of second insulating layer 52 include, but not limited to, the heat conductivity between 1.1 W/m·K and 1.6 W/m·K, inclusive.

In the present embodiment, first surface 21 is a surface of first insulating layer 51 at the positive side of the z axis and second surface 22 is a surface of second insulating layer 52 at the negative side of the z axis.

Thermoelectric conversion units 3, which are a kind of thermoelectric elements, include elements that perform thermoelectric conversion. Specific examples of thermoelectric conversion units 3 include Peltier devices.

Each of thermoelectric conversion units 3 includes first thermoelectric member 31, second thermoelectric member 32, and first electrode 41.

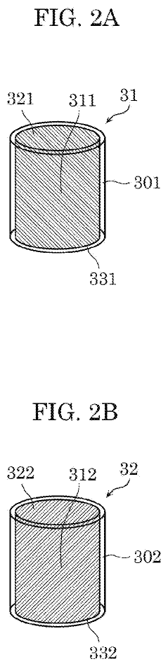

FIG. 2A is a schematic perspective view of an example of first thermoelectric member 31 according to Embodiment 1. As shown in FIG. 2A, first thermoelectric member 31 includes first tubular member 301 having insulation property and first semiconductor 311.

First tubular member 301 may be any tubular member having insulation property and including openings at both ends of the tubular member. First tubular member 301 has, for example, the length (the length in the z axis direction) between 0.4 mm and 2.0 mm, inclusive, the outer diameter between 0.4 mm and 2.0 mm, inclusive, the inner diameter between 0.39 mm and 1.88 mm, inclusive, and the thickness between 0.005 mm and 0.1 mm, inclusive. Note that the length (the length in the z axis direction) of first tubular member 301 is the same as the length (the length in the z axis direction) of first thermoelectric member 31 described above.

The thermal expansion coefficient of first tubular member 301 may be smaller than the thermal expansion coefficient of insulating substrate 2. Specific examples of first tubular member 301 include a glass tube.

First semiconductor 311 is filled inside of first tubular member 301. Specific examples of first semiconductor 311 include a p-type semiconductor. The p-type semiconductor may comprise any material having thermoelectric conversion property. A bismuth telluride compound, for example, may be used from the standpoint of usage environment, etc.

End surface 321 is a surface region at one end of first tubular member 301 and first semiconductor 311, and end surface 331 is a surface region at the other end of first tubular member 301 and first semiconductor 311. In the present embodiment, end surface 321 is located at the positive side of the z axis (at the side of first surface 21) and end surface 331 is located at the negative side of the z axis (at the side of second surface 22).

As shown in FIG. 2A, first thermoelectric member 31 has a circular cylindrical shape. The lateral surface of the circular cylindrical shape is also described as the lateral surface of first thermoelectric member 31.

End portion 341 may be disposed to seal one end (i.e., end surface 321) of first tubular member 301 filled with first semiconductor 311 and end portion 351 may be disposed to seal the other end (i.e., end surface 331) of first tubular member 301. End portion 341 is located at the side of first surface 21 of insulating substrate 2 and end portion 351 is located at the side of second surface 22 of insulating substrate 2.

End portion 341 includes: a barrier film that seals the opening at one end of first tubular member 301 by directly contacting the opening; and a joining layer that contacts the barrier film. The barrier film includes a Ti layer and an Ni layer.

In the barrier film, the Ti layer contacts first semiconductor 311 by directly sealing the opening at one end of first tubular member 301 and the Ni layer contacts the joining layer. The joining layer includes a joining member comprising, for example, Sn, Au, Ag, or Cu. For example, the thickness of the Ti layer (i.e., the thickness in the z axis direction) is between 0.02 μm and 0.3 μm, inclusive, the thickness of the Ni layer (i.e., the thickness in the z axis direction) is between 0.5 μm and 10 μm, inclusive, and the thickness of the joining layer (i.e., the thickness in the z axis direction) is between 0.1 μm and 100 μm, inclusive. End portion 351 has the same configuration as that of end portion 341. Note that the Ti layer, the Ni layer, and the joining layer are laminated in end portion 351 in stated order in a direction from first tubular member 301 and first semiconductor 311 to second surface 22.

The Ti layer, which has a high barrier property, is capable of enhancing the reliability of the thermoelectric conversion substrate. The Ti layer, however, can be formed only by spattering which requires a vacuum chamber, meaning that an increased cost is required in the manufacture of the Ti layer. In view of this concern, the Ti layer may be excluded. In this case, the thickness of the other layers (the Ni layer and the joining layer) are different; the thickness of the Ni layer may be between 5 μm and 50 μm, inclusive, in the configuration without the Ti layer, and the thickness of the joining layer is the same even without the Ti layer and thus may be between 0.1 μm and 100 μm, inclusive.

FIG. 2B is a schematic perspective view of an example of second thermoelectric member 32 according to Embodiment 1. As shown in FIG. 2B, second thermoelectric member 32 includes second tubular member 302 having insulation property and second semiconductor 312.

Second tubular member 302 may be any tubular member having insulation property and including openings at both ends of the tubular member.

The thermal expansion coefficient of second tubular member 302 may be smaller than the thermal expansion coefficient of insulating substrate 2. The dimension and the material of second tubular member 302 may be the same as the dimension and the material of first tubular member 301.

Second semiconductor 312 is filled inside of second tubular member 302. The carriers of second semiconductor 312 are different from the carriers of first semiconductor 311. When the carriers of first semiconductor 311 are positive holes, the carriers of second semiconductor 312 are electrons, or may be vice versa.

Specific examples of second semiconductor 312 include an n-type semiconductor. The n-type semiconductor may comprise any material having thermoelectric conversion property. A bismuth telluride compound, for example, may be used from the standpoint of usage environment, etc.

End surface 322 is a surface region at one end of second tubular member 302 and second semiconductor 312, and end surface 332 is a surface region at the other end of second tubular member 302 and second semiconductor 312. In the present embodiment, end surface 322 is located at the positive side of the z axis (at the side of first surface 21) and end surface 332 is located at the negative side of the z axis (at the side of second surface 22).

As shown in FIG. 2B, second thermoelectric member 32 has a circular cylindrical shape. The lateral surface of the circular cylindrical shape is also described as the lateral surface of second thermoelectric member 32.

End portion 342 may be disposed to seal one end (i.e., end surface 322) of second tubular member 302 filled with second semiconductor 312, and end portion 352 may be disposed to seal the other end (i.e., end surface 332) of second tubular member 302. End portion 342 is located at the side of first surface 21 of insulating substrate 2 and end portion 352 is located at the side of second surface 22 of insulating substrate 2. End portions 342 and 352 of second thermoelectric member 32 have the same configurations as those of end portions 341 and 351 of first thermoelectric member 31.

In thermoelectric conversion substrate 1 shown in FIG. 1, first semiconductors 311 and second semiconductors 312 are protected by first tubular members 301 and second tubular members 302, respectively. This configuration reduces the breakage of thermoelectric conversion units 3 even when insulating substrate 2 is under a load. Example directions of a load imposed on insulating substrate 2 include, but not limited to, the thickness direction.

First surface 21 of insulating substrate 2 and end surface 321 of each first thermoelectric member 31 at the side of first surface 21 may be spaced apart from each other in the thickness direction of insulating substrate 2. A level difference between first surface 21 and end surface 321 prevents end surface 321 from being directly subjected to a load that is imposed on first surface 21 in the thickens direction. This consequently further reduces the breakage of first thermoelectric member 31. Similarly, first surface 21 of insulating substrate 2 and end surface 322 of each second thermoelectric member 32 at the side of first surface 21 are spaced apart from each other in the thickness direction of insulating substrate 2. In this case, too, a level difference between first surface 21 and end surface 322 prevents end surface 322 from being directly subjected to a load that is imposed on first surface 21 in the thickens direction. This consequently further reduces the breakage of second thermoelectric member 32. The foregoing level differences, i.e., the distance between first surface 21 and end surface 321 and between first surface 21 and end surface 322 are, for example, between 25 μm and 200 μm, inclusive.

Second surface 22 of insulating substrate 2 and end surface 331 of each first thermoelectric member 31 at the side of second surface 22 may be spaced apart from each other in the thickness direction of insulating substrate 2. A level difference between second surface 22 and end surface 331 prevents end surface 331 from being directly subjected to a load that is imposed on second surface 22 in the thickens direction. This consequently further reduces the breakage of first thermoelectric member 31. Similarly, second surface 22 of insulating substrate 2 and end surface 332 of each second thermoelectric member 32 at the side of second surface 22 are spaced apart from each other in the thickness direction of insulating substrate 2. In this case, too, a level difference between second surface 22 and end surface 332 prevents end surface 332 from being directly subjected to a load that is imposed on second surface 22 in the thickens direction. This consequently further reduces the breakage of second thermoelectric member 32. The foregoing level differences, i.e., the distance between second surface 22 and end surface 331 and between second surface 22 and end surface 332 are, for example, between 25 μm and 200 μm, inclusive.

A plurality of thermoelectric conversion units 3 are electrically connected in series in a manner that first thermoelectric member 31 and second thermoelectric member 32 are alternately arranged. In the present embodiment, first thermoelectric member 31 of thermoelectric conversion unit 3a, second thermoelectric member 32 of thermoelectric conversion unit 3a, first thermoelectric member 31 of thermoelectric conversion unit 3b, and second thermoelectric member 32 of thermoelectric conversion unit 3b are alternately arranged.

Note that a plurality of thermoelectric conversion units 3 are electrically connected in series by first electrodes 41 and second electrode 42.

As shown in FIG. 1, first electrodes 41 are disposed on first surface 21 of insulating substrate 2. Specific examples of the material of first electrodes 41 include, but not limited to, Cu and Al having low electric resistance. Each first electrode 41 electrically connects first thermoelectric member 31 and second thermoelectric member 32.

Even more specifically, each first electrode 41 electrically connects first semiconductor 311 of first thermoelectric member 31 and second semiconductor 312 of second thermoelectric member 32. In the case where first thermoelectric member 31 includes end portion 341, each first electrode 41 is electrically connected to first semiconductor 311 via end portion 341. Similarly, in the case where second thermoelectric member 32 includes end portion 342, each first electrode 41 is electrically connected to second semiconductor 312 via end portion 342.

Second electrode 42 is disposed on second surface 22 of insulating substrate 2. Second electrode 42 electrically connects first thermoelectric member 31 of one of thermoelectric conversion units 3 and second thermoelectric member 32 of another of thermoelectric conversion units 3. In the present embodiment, second electrode 42 electrically connects first thermoelectric member 31 of thermoelectric conversion unit 3a and second thermoelectric member 32 of thermoelectric conversion unit 3b. Stated differently, second electrode 42 electrically connects adjacent thermoelectric conversion units 3.

Even more specifically, second electrode 42 is electrically connected to first semiconductor 311 of first thermoelectric member 31. In the case where first thermoelectric member 31 includes end portion 351, second electrode 42 is electrically connected to first semiconductor 311 via end portion 351. Second electrode 42 is electrically connected to second semiconductor 312 of second thermoelectric member 32. In the case where second thermoelectric member 32 includes end portion 352, second electrode 42 is electrically connected to second semiconductor 312 via end portion 352.

Also, electrodes for connection to a power source (hereinafter described as power source connection electrodes) may be further disposed.

For example, in the present embodiment, power source connection electrodes 412 and 422 are disposed on second surface 22 of insulating substrate 2. Second electrode 42 may serve as a power source connection electrode. Second electrode 42 may be, for example, power source connection electrode 412. In the present embodiment, second electrode 42 electrically connects adjacent thermoelectric conversion units 3, and is connected to a direct-current power source. Power source connection electrodes 412 and 422 are electrically insulated from each other.

Although not illustrated in the drawings, a line extends from each of power source connection electrodes 412 and 422 for connection to the direct-current power source.

When a voltage is applied across power source connection electrodes 412 and 422 which have been connected to the direct-current power source, a direct current passes therethrough. Consequently, heat is transferred from one surface to another surface of insulating substrate 2 due to the Peltier effect. Suppose, for example, that first semiconductor 311 is a p-type semiconductor and second semiconductor 312 is an n-type semiconductor. In this case, a direct current flows in a direction from second semiconductor 312 to first semiconductor 311, thereby transferring heat from first surface 21 to second surface 22 of insulating substrate 2. When the polarity of the direct-current power source is reversed to change the flow direction of the direct current, heat is also transferred in the opposite direction. This enables to freely switch between cooling and heating. Note that the Seebeck effect, which is opposite to the Peltier effect, may be utilized. In this case, a temperature difference is applied between first surface 21 and second surface 22 of insulating substrate 2 to generate a potential difference, thereby extracting electrical energy.

Also, each first electrode 41 and second electrode 42 may include filled vias. Each first electrode 41 may be connected to end portion 341 and end portion 342 via filled vias. Second electrode 42 may be connected to end portion 351 and end portion 352 via filled vias. More specifically, each first electrode 41 includes first filled via 201 and second filled via 202. Second electrode 42 includes third filled via 211 and fourth filled via 212.

The following describes the filled vias according to the present embodiment.

First filled via 201 is disposed on first surface 21 of insulating substrate 2. First filled via 201 may be formed as described below. A first opening portion that penetrates through first insulating layer 51 is disposed above end portion 341. In the formation of each first electrode 41, the inside of the first opening portion is plated with a conductive material, thereby forming first filled via 201. First filled via 201 extends from first surface 21 of insulating substrate 2 to end portion 341 of first thermoelectric member 31 at the side of first surface 21. The bottom surface of first filled via 201 may contact end portion 341 of first thermoelectric member 31.

Second filled via 202 is disposed on first surface 21 of insulating substrate 2. Second filled via 202 may be formed as described below. A second opening portion that penetrates through first insulating layer 51 is disposed above end portion 342. In the formation of each first electrode 41, the inside of the second opening portion is plated with a conductive material, thereby forming second filled via 202. Second filled via 202 extends from first surface 21 of insulating substrate 2 to end portion 342 of second thermoelectric member 32 at the side of first surface 21. The bottom surface of second filled via 202 may contact end portion 342 of second thermoelectric member 32.

Third filled via 211 is disposed on second surface 22 of insulating substrate 2. Third filled via 211 may be formed as described below. A third opening portion that penetrates through second insulating layer 52 is disposed below end portion 351. In the formation of second electrode 42, the inside of the third opening portion is plated with a conductive material, thereby forming third filled via 211. Third filled via 211 extends from second surface 22 of insulating substrate 2 to end portion 351 of first thermoelectric member 31 at the side of second surface 22. The bottom surface of third filled via 211 may contact end portion 351 of first thermoelectric member 31.

Fourth filled via 212 is disposed on second surface 22 of insulating substrate 2. Fourth filled via 212 may be formed as described below. A fourth opening portion that penetrates through second insulating layer 52 is disposed below end portion 352. In the formation of second electrode 42, the inside of the fourth opening portion is plated with a conductive material, thereby forming fourth filled via 212. Fourth filled via 212 extends from second surface 22 of insulating substrate 2 to end portion 352 of second thermoelectric member 32 at the side of second surface 22. The bottom surface of fourth filled via 212 may contact end portion 352 of second thermoelectric member 32.

The following describes insulating film 61, electronic component 7, thermally conductive layer 62, and heatsink 70 included in thermoelectric conversion module 10.

Insulating film 61 is disposed in contact with first surface 21 or second surface 22 of insulating substrate 2 of thermoelectric conversion substrate 1. Insulating film 61 in the present embodiment is disposed on first surface 21, but may be disposed on second surface 22. Insulating film 61 may be any sheet having insulation property. Insulating film 61 is, for example, a sheet formed by impregnating a reinforcing material with a thermosetting resin composition, and curing the resultant. Insulating film 61 may also be formed by curing a thermosetting resin composition in a sheet form, without including a reinforcing material. Alternatively, as with solder resist, insulating film 61 may be formed by applying a resin material before being cured onto thermoelectric conversion substrate 1, and curing the resultant.

Electronic component 7 is mounted on thermoelectric conversion substrate 1 via insulating film 61. Specific examples of electronic component 7 include a large-scale integration (LSI) and a power device. Although not illustrated in the drawings, a line, a land, a through-hole, etc. are disposed in insulating film 61, where necessary, when electronic component 7 is mounted on thermoelectric substrate 1 via insulating film 61. In some cases, electronic component 7 generates heat under application of an electric current.

Thermally conductive layer 62 may be disposed on second surface 22 of insulating substrate 2, and heatsink 70 may be attached to thermally conductive layer 62. Stated differently, insulating substrate 2 may be sandwiched between insulating film 61 and thermally conductive layer 62. Thermally conductive layer 62 comprises a thermal interface material (TIM) such as grease. Heatsink 70 includes projected portions, for example, to have an increased surface area. Specific examples of the material of heatsink 70 include Cu and Al.

As described above, a voltage is applied across power source connection electrodes 412 and 422 which have been connected to the direct-current power source, a direct current passes therethrough. Consequently, heat is transferred from one surface to another surface of insulating substrate 2 due to the Peltier effect. Suppose, for example, that first semiconductor 311 is a p-type semiconductor and second semiconductor 312 is an n-type semiconductor. In this case, when a direct current flows in a direction from second semiconductor 312 to first semiconductor 311, heat generated in electronic component 7 and transferred to insulating film 61 is forced to move from first surface 21 to second surface 22 of insulating substrate 2 to be released from heatsink 70 via thermally conductive layer 62.

The following describes stress relaxation portions 8 included in thermoelectric conversion substrate 1.

In the present embodiment, each stress relaxation portion 8 is disposed between first thermoelectric member 31 and second thermoelectric member 32.

The following describes stress relaxation portions 8, using Examples 1 through 3.

### Example 1

Each stress relaxation portion 8 in Example 1 is, for example, hollow 81 disposed between first thermoelectric member 31 and second thermoelectric member 32 in thermoelectric conversion substrate 1. More specifically, as shown in FIG. 1, hollows 81 (stress relaxation portions 8) are incorporated in insulating substrate 2 in the thickness direction of insulating substrate 2. Even more specifically, hollows 81 penetrate through core insulating layer 50 in the thickness direction of insulating substrate 2, and are located between first insulating layer 51 and second insulating layer 52.

For example, heat generated in electronic component 7 can cause a thermal expansion difference between core insulating layer 50, first insulating layer 51 or second insulating layer 52 and first tubular members 301 or second tubular members 302, as a result of which stress can be generated. Such stress causes a possible breakage of first tubular members 301 and second tubular members 302.

The configuration including hollows 81 (stress relaxation portions 8) as described above facilitates the movement of stress toward hollows 81, and makes it hard for the stress to move toward first tubular members 301 and second tubular members 302. Stated differently, hollows 81 are capable of absorbing stress. More specifically, hollows 81 deform (e.g., contract) under stress, thereby reducing the breakage of first tubular members 301 and second tubular members 302 under stress. This consequently reduces the breakage of first semiconductors 311 and second semiconductors 312 incorporated in first tubular members 301 and second tubular members 302, thereby enabling the user to use a desired function. The foregoing configuration thus enables thermoelectric conversion substrate 1 that reduces the breakage of thermoelectric conversion units 3. Stress relaxation portions 8 are not limited to the foregoing hollows 81; stress relaxation portions 8 capable of stress relaxation thus enable thermoelectric conversion substrate 1 that reduces the breakage of thermoelectric conversion units 3 as with the foregoing configuration.

Note that the reduction of the breakage of at least one of first tubular member 301, second tubular member 302, first semiconductor 311, or second semiconductor 312 is regarded as having reduced the breakage of thermoelectric conversion units 3.

The distance between each hollow 81 and the lateral surface of first thermoelectric member 31 and second thermoelectric member 32 is between 0.05 mm and 1.7 mm, inclusive. For example, such distance is the distance between hollow 81 and first thermoelectric member 31 of thermoelectric conversion unit 3a and the distance d1 shown in FIG. 1.

With distance d1 in the foregoing range, hollows 81 are more capable of absorbing the foregoing stress. This configuration thus further reduces the breakage of first semiconductors 311 and second semiconductors 312.

Example shapes of each stress relaxation portion 8 (hollow 81) in a plan view include, but not limited to, a circular shape, an oval shape, and a polygonal shape.

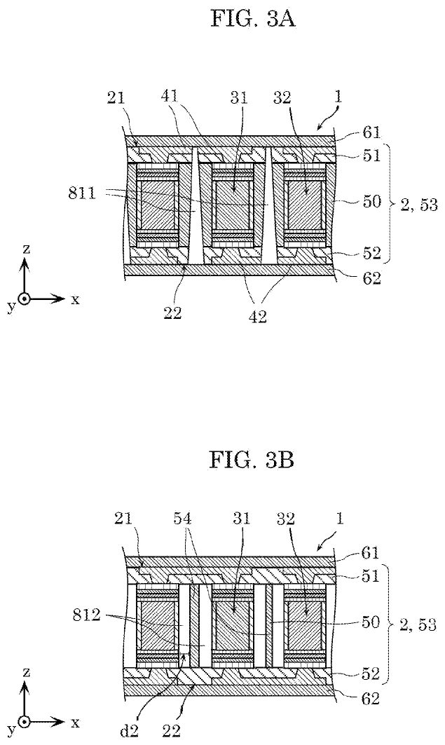

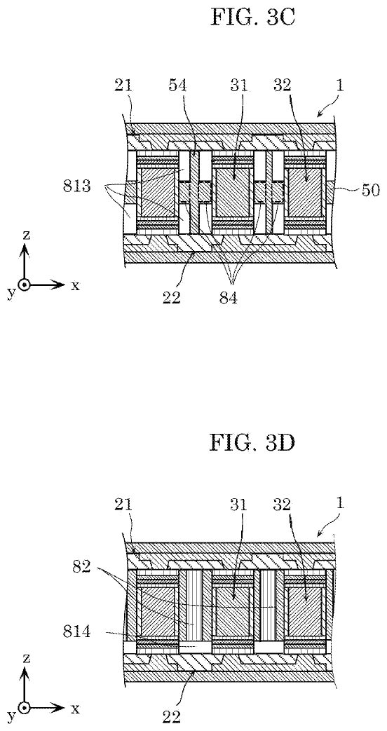

With reference to FIG. 3A, hollows 811 as through-holes will be described. FIG. 3A is a schematic cross-sectional view of an example of thermoelectric conversion substrate 1 according to Example 1 of Embodiment 1. Hollows 811 penetrate through first surface 21 and second surface 22 in the thickness direction of insulating substrate 2. Hollows 811 may also be through-holes that penetrate through insulating substrate 2 in the thickness direction from insulating film 61 to thermally conductive layer 62.

Note that hollows 81 and hollows 811 both have any shapes.

The configuration including hollows 811 (stress relaxation portions 8) penetrating through first surface 21 and second surface 22 facilitates the movement of the foregoing stress toward hollows 811, and makes it hard for the stress to move toward first tubular members 301 and second tubular members 302. Stated differently, hollows 811 are capable of absorbing stress. More specifically, hollows 811 deform (e.g., contract) under stress, thereby reducing the breakage of first tubular members 301 and second tubular members 302 under stress.

This consequently reduces the breakage of first semiconductors 311 and second semiconductors 312 incorporated in first tubular members 301 and second tubular members 302, thereby enabling the user to use a desired function.

Note that, in FIG. 3A, hollow 811 penetrates through first electrode 41, which is thus illustrated as two separated first electrodes 41. However, these two first electrodes 41 are integrated in a region not illustrated in the drawing (e.g., a region closer to the positive or negative side of the y axis than the cross-section shown in FIG. 3A). Such first electrode 41 in an integrated form electrically connects first thermoelectric member 31 and second thermoelectric member 32. The same is true of second electrode 42.

Also note that hollow 81 or hollow 811 may be in fluid communication with adjacent hollow 81 or hollow 811. For example, hollow 81 between first thermoelectric member 31 and second thermoelectric member 32 of thermoelectric conversion unit 3a and hollow 81 between first thermoelectric member 31 of thermoelectric conversion unit 3a and second thermoelectric member 32 of thermoelectric conversion unit 3b are adjacent hollows 81. These two adjacent hollows 81 may be in fluid communication with each other.

Also, as shown in FIG. 3A, in a plan view of each hollow 811 on first surface 21 or second surface 22, the area of hollow 811 on the cooling side of thermoelectric conversion unit 3 may be smaller than the area of hollow 811 on the heat dissipation side of thermoelectric conversion unit 3. In the present embodiment, first surface 21 serves as the cooling side and second surface 22 serves as the heat dissipation side. Stated differently, the opening of each hollow 811 on the cooling side may be smaller and the opening of each hollow 811 on the heat dissipation side may be larger.

This configuration alleviates a distortion inside of thermoelectric conversion substrate 1 caused by a thermal expansion difference between the cooling side and the heat dissipation side that occurs when thermoelectric conversion substrate 1 is under application of an electric current. This configuration is thus capable of reducing the breakage of first thermoelectric members 31 and second thermoelectric members 32 under the foregoing stress.

Also, a difference between the area of each hollow 811 on the cooling side and the area of hollow 811 on the heat dissipation side may be between 0.1 μm² and 0.1 mm², inclusive. An example case will be described where the reflow temperature condition of lead-free solder in the actual mounting process is 260° C. and the coefficient of linear expansion of insulating substrate 2 is, for example, 15×10⁻⁶/° C. In this case, from the standpoint of the coefficient of linear expansion, the difference between the area of the opening of each hollow 811 on the cooling side and the area of the opening of hollow 811 on the heat dissipation side may be between 0.1 μm² and 0.1 mm², inclusive, as described above. With the difference below 0.1 μm², it would be hard to alleviate a distortion inside of thermoelectric conversion substrate 1 caused by a thermal expansion difference between the cooling side and the heat dissipation side that occurs when thermoelectric conversion substrate 1 is under application of an electric current. In contrast, the difference greater than 0.1 μm² would produce a greater expansion difference between core insulating layer 50 and first insulating layer 51 or second insulating layer 52, as a result of which core insulating layer 50 is removed from first insulating layer 51 or second insulating layer 52.

With the difference between the area of each hollow 811 on the cooling side and the area of hollow 811 on the heat dissipation side within the foregoing range, the breakage of first thermoelectric member 31 and second thermoelectric member 32 under the foregoing stress is further reduced.

With reference to FIG. 3B, hollows 812 will be described. FIG. 3B is a schematic cross-sectional view of an example of thermoelectric conversion substrate 1 according to Example 1 of Embodiment 1. Each hollow 812 is disposed adjacent to the lateral surface of first thermoelectric member 31 or second thermoelectric member 32.

In this case, as shown in FIG. 3B, hollow 812 and part 54 of core insulating layer 50 may be disposed between first thermoelectric member 31 and second thermoelectric member 32. In a cross-sectional view shown in FIG. 3B, part 54 of core insulating layer 50 is a region in core insulating layer 50 that extends in the thickness direction of insulating substrate 2. Each hollow 812 is located between part 54 of core insulating layer 50 and first thermoelectric member 31 or second thermoelectric member 32.

Part 54 of core insulating layer 50 may be sandwiched between two hollows 812. Stated differently, insulating substrate 2 (more specifically, part 54 of core insulating layer 50) may be disposed not to contact the lateral surface of first thermoelectric member 31 or second thermoelectric member 32.

Each hollow 812 disposed adjacent to the lateral surface of first thermoelectric member 31 or second thermoelectric member 32 enables first thermoelectric member 31 or second thermoelectric member 32 to be less affected by stress generated by thermal expansion of core insulating layer 50. This is because hollows 812 absorb stress generated by thermal expansion of core insulating layer 50. Stated differently, each hollow 812 prevents the lateral surface of first thermoelectric member 31 or second thermoelectric member 32 from being compressed by stress, thereby reducing the breakage of first thermoelectric member 31 or second thermoelectric member 32.

Distance d2 between part 54 of core insulating layer 50 and the lateral surface of first thermoelectric member 31 or second thermoelectric member 32 may be between 0.05 mm and 1.7 mm, inclusive. An example case will be described where the reflow temperature condition of lead-free solder in the actual mounting process is 260° C. and the coefficient of linear expansion of insulating substrate 2 is, for example, 15×10⁻⁶/° C. In this case, from the standpoint of the coefficient of linear expansion, distance d2 between insulating substrate 2 (part 54 of core insulating layer 50) and the lateral surface of first thermoelectric member 31 or second thermoelectric member 32 may be between 0.05 mm and 1.7 mm, inclusive, as described above.

In this configuration, each hollow 812 enables first thermoelectric member 31 or second thermoelectric member 32 to be less affected by stress generated by thermal expansion of core insulating layer 50. Stated differently, each hollow 812 prevents the lateral surface of first thermoelectric member 31 or second thermoelectric member 32 from being compressed by stress, thereby reducing the breakage of first thermoelectric member 31 or second thermoelectric member 32.

However, with hollows 812 in a state shown in FIG. 3B, it is difficult for first thermoelectric members 31 or second thermoelectric members 32 to stand upright in the manufacture of thermoelectric conversion substrate 1. Note that “to stand upright” means, for example, that the lengths of first thermoelectric members 31 and second thermoelectric members 32 in a longitudinal direction in a cross-sectional view match the length of insulating substrate 2 in the thickness direction of insulating substrate 2. In view of this, with reference to FIG. 3C, an embodiment to address such difficulty will be described.

FIG. 3C is a schematic cross-sectional view of another example of thermoelectric conversion substrate 1 according to Example 1 of Embodiment 1. As shown in FIG. 3C, protruded portions 84 protruding from parts 54 of core insulating layer 50 may be disposed. Each protruded portion 84 is incorporated in insulating substrate 2 in the thickness direction of insulating substrate 2, and contacts the lateral surface of first thermoelectric member 31 or second thermoelectric member 32. In FIG. 3C, protruded portions 84 are regions defined by the dashed lines. Each protruded portion 84 protrudes from part 54 of core insulating layer 50 in a direction perpendicular to the thickness direction of insulating substrate 2. In a cross-sectional view, each protruded portion 84 is located on part 54 of core insulating layer 50 inside of thermoelectric conversion substrate 1 to partially contact the lateral surface of first thermoelectric member 31 or second thermoelectric member 32. Hollows 813 are located above and below each protruded portion 84.

This configuration enables first thermoelectric members 31 or second thermoelectric members 32 to easily stand upright. Stated differently, each protruded portion 84 supports and holds first thermoelectric member 31 or second thermoelectric member 32, thereby preventing first thermoelectric member 31 or second thermoelectric member 32 from falling over. This configuration thus reduces the breakage of first thermoelectric members 31 or second thermoelectric members 32.

Each protruded portion 84 may contact first thermoelectric member 31 or second thermoelectric member 32 in a manner that protruded portion 84 surrounds the lateral surface of first thermoelectric member 31 or second thermoelectric member 32. In the present embodiment, each protruded portion 84 contacts first thermoelectric member 31 or second thermoelectric member 32 in a manner that protruded portion 84 surrounds the lateral surface of first thermoelectric member 31 or second thermoelectric member 32 having a circular cylindrical shape. With this configuration, first thermoelectric members 31 or second thermoelectric members 32 are supported and held in a more stable manner, thereby further reducing the breakage of first thermoelectric members 31 or second thermoelectric members 32.

The length of each protruded portion 84 in the thickens direction of insulating substrate 2 is between 0.1 mm and 1.2 mm, inclusive. An example case will be described where the reflow temperature condition of lead-free solder in the actual mounting process is 260° C. and the coefficient of linear expansion of insulating substrate 2 is, for example, 15×10⁻⁶1° C. In this case, protruded portions 84 in the length greater than 1.2 mm in the thickness direction of insulating substrate 2 would compress the lateral surfaces of first thermoelectric members 31 or second thermoelectric members 32 to result in the possible breakage of tubular members. Also in this case, protruded portions 84 in the length less than 0.1 mm in the thickness direction of insulating substrate 2 would have a difficulty in supporting first thermoelectric members 31 or second thermoelectric members 32 in a stable manner.

Protruded portions 84 having the length in the foregoing range in the thickness direction of insulating substrate 2 are thus capable of supporting first thermoelectric members 31 or second thermoelectric members 32 in a more stable manner. This configuration thus further reduces the breakage of first thermoelectric members 31 or second thermoelectric members 32.

### Example 2

Stress relaxation portions 8 in Example 1 are hollows, but the present disclosure is not limited to this. In Example 2, stress relaxation portions 8 are protective materials.

With reference to FIG. 1 again, Example 2 will be described.

Each stress relaxation portion 8 in Example 2 is, for example, protective material 82 disposed between first thermoelectric member 31 and second thermoelectric member 32 in thermoelectric conversion substrate 1. More specifically, as shown in FIG. 1, protective materials 82 (stress relaxation portions 8) are incorporated in insulating substrate 2 in the thickness direction of insulating substrate 2. Even more specifically, protective materials 82 penetrate through core insulating layer 50 in the thickness direction of insulating substrate 2 and are located between first insulating layer 51 and second insulating layer 52. Stated differently, protective materials 82 in the present embodiment have the same shape as that of hollows 81. Protective materials 82 may comprise, for example, an elastically deformable material. The configuration including protective materials 82 as described above facilitates the movement of stress generated by the foregoing thermal expansion difference toward protective materials 82, and makes it hard for the stress to move toward first tubular members 301 and second tubular members 302. Stated differently, protective materials 82 are capable of absorbing stress. More specifically, the volumes of protective materials 82 contract under stress, thereby reducing the breakage of first tubular members 301 and second tubular members 302 under stress.

The distance between each protective material 82 and the lateral surface of first thermoelectric member 31 or second thermoelectric member 32 may be 1.7 mm or less. The distance between each protective material 82 and the lateral surface of first thermoelectric member 31 or second thermoelectric member 32 may be 0.05 mm or greater. With the distance in the foregoing range, even when the foregoing stress is generated, the volumes of protective materials 82 contract under such stress. The breakage of first thermoelectric members 31 and second thermoelectric members 32 under stress is thus further reduced.

Although not illustrated in the drawings, protective materials 82 (stress relaxation portions 8) may penetrate through first surface 21 and second surface 22 in the thickness direction of insulating substrate 2. In this case, protective materials 82 may penetrate through insulating substrate 2 in the thickness direction from insulating film 61 to thermally conductive layer 62. Note that protective materials 82 have any shapes.

The configuration including protective materials 82 as described above reduces the breakage of first thermoelectric members 31 and second thermoelectric members 32 even when the foregoing stress is generated because the volumes of protective materials 82 contract under such stress.

Also note that protective material 82 may be in fluid communication with adjacent protective material 82. For example, protective material 82 between first thermoelectric member 31 and second thermoelectric member 32 of thermoelectric conversion unit 3a and protective material 82 between first thermoelectric member 31 of thermoelectric conversion unit 3a and second thermoelectric member 32 of thermoelectric conversion unit 3b are adjacent protective materials. These two adjacent protective materials 82 may be in fluid communication with each other.

The hardness of protective materials 82 may be lower than the hardness of insulating substrate 2. With this, even when the foregoing stress is generated, the volumes of protective materials 82 easily contract under such stress, thereby further reducing the breakage of first thermoelectric members 31 and second thermoelectric members 32 under stress.

Protective materials 82 may comprise, for example, silicone rubber. The configuration including such protective materials 82 (silicone rubbers) further reduces the breakage of first thermoelectric members 31 and second thermoelectric members 32 under stress.

Under a condition that the bending elastic modulus of insulating substrate 2 is between 5 GPa and 30 GPa, inclusive, the Shore A hardness of the silicone rubbers may be 30 and 80, inclusive. The present disclosure, however, is not limited to this. With this, even when the foregoing stress is generated, the volumes of protective materials 82 easily contract under such stress, thereby further reducing the breakage of first thermoelectric members 31 and second thermoelectric members 32 under stress.

The thickness of the silicone rubbers may be between 0.05 mm and 1.5 mm, inclusive. Note that the thickness of the silicone rubbers refers to the thickness in a perpendicular direction (the x axis direction) that is normal to the thickness direction (the z axis direction) of insulating substrate 2.

With the silicone rubbers having the thickness in the foregoing range, even when the foregoing stress is generated, the volumes of protective materials 82 easily contract under such stress, thereby further reducing the breakage of first thermoelectric members 31 and second thermoelectric members 32 under stress.

Here, an example case will be described where the reflow temperature condition of lead-free solder in the actual mounting process is 260° C. and the coefficient of linear expansion of insulating substrate 2 is, for example, 15×10⁻⁶/° C. In general, the volume expansion coefficient of silicone rubber is 6 to 8×1⁻⁴ cm³/cm³/° C. As such, the silicone rubbers in the thickness greater than 1.5 mm would expand and compress the inner portion of thermoelectric conversion substrate 1. This results in a possible breakage of first tubular members 301 and second tubular members 302. With reference to FIG. 3D, an embodiment to address such problem will be described.

FIG. 3D is a schematic cross-sectional view of an example of thermoelectric conversion substrate 1 according to Example 2 of Embodiment 1. As shown in FIG. 3D, at least one hollow 814 may be disposed between protective material 82 and at least one of first surface 21 or second surface 22. In the present embodiment, hollow 814 is disposed between second surface 22 and protective material 82 (silicone rubber). With this configuration, each protective material 82 (silicone rubber), even when it expands due to heat, moves to hollow 814, thus preventing the inner portion of thermoelectric conversion substrate 1 from being compressed. This configuration thus further reduces the breakage of first tubular members 301 and second tubular members 302. Here, the closer to the surface at the heat dissipation side (in the present embodiment, second surface 22) hollow 814 is located, the more effectively the breakage of first tubular member 301 and second tubular member 302 is reduced.

The length of hollow 814 in the thickens direction of insulating substrate 2 may be between 0.05 mm and 0.2 mm, inclusive. The length between hollow 814 and the lateral surface of first thermoelectric member 31 or second thermoelectric member 32 may be between 0.05 mm and 1.5 mm, inclusive.

With hollow 814 having the length in the foregoing range, each protective material 82 (silicone rubber), even when it expands due to heat, moves to hollow 814, thus preventing the inner portion of thermoelectric conversion substrate 1 from being compressed. This configuration thus further reduces the breakage of first tubular member 301 and second tubular member 302.

Thermoelectric conversion substrate 1 according to Embodiment 1 has the foregoing configuration. As thus described, heat from electronic component 7 can cause a thermal expansion difference between core insulating layer 50, first insulating layer 51, or second insulating layer 52 and first tubular members 301 or second tubular members 302, as a result of which stress can be generated. The configuration including stress relaxation portions 8 facilitates the movement of stress toward stress relaxation portions 8, and makes it hard for the stress to move toward first tubular members 301 and second tubular members 302. Stated differently, stress relaxation portions 8 deform under stress, thereby reducing the breakage of first tubular members 301 and second tubular members 302 under stress. This consequently reduces the breakage of first semiconductors 311 or second semiconductors 312 incorporated in first tubular members 301 or second tubular members 302, thereby enabling the thermoelectric conversion substrate to exercise a desired function. This configuration thus enables thermoelectric conversion substrate 1 that reduces the breakage of thermoelectric conversion units 3.

Thermoelectric conversion module 10 includes thermoelectric conversion substrate 1 including stress relaxation portions 8. As such, the present disclosure enables thermoelectric conversion module 10 including thermoelectric conversion substrate 1 capable of reducing the breakage of thermoelectric conversion units 3.

It is easy to envisage that various stress relaxation portions 8 in the foregoing embodiments disposed on insulating substrate 2 enable to achieve desired effects. It is thus regarded as easy to envisage stress relaxation portions 8 from the present disclosure without departing from such an envisagement.

### Example 3

Stress relaxation portions 8 are hollows in Example 1 and are protective materials in Example 2, but the present disclosure is not limited to these.

In Example 3, stress relaxation portions 8 are thermal conduction portions. With reference to FIG. 1 again, Example 3 will be described.

Each stress relaxation portion 8 in Example 3 is, for example, a thermal conduction portion disposed between first thermoelectric member 31 and second thermoelectric member 32 in thermoelectric conversion substrate 1. The heat conductivity of the thermal conduction portions may be, for example, higher than the heat conductivity of insulating substrate 2. Each thermal conduction portion attracts heat propagating around first thermoelectric member 31 or second thermoelectric member 32 and dissipates the heat to outside.

This configuration prevents heat generated in electronic component 7 from causing a thermal expansion difference between core insulating layer 50, first insulating layer 51, or second insulating layer 52 and first tubular members 301 or second tubular members 302. For this reason, stress is hard to be generated due to a thermal expansion difference. This reduces the breakage of first tubular members 301 and second tubular members 302. This consequently reduces the breakage of first semiconductors 311 and second semiconductors 312 incorporated in first tubular members 301 and second tubular members 302, thereby enabling the user to use a desired function.

The thermal conduction portions in the present embodiment are high thermal conductors 83. More specifically, as shown in FIG. 1, the thermal conduction portions (high thermal conductors 83) are incorporated in insulating substrate 2 in the thickness direction of insulating substrate 2. Even more specifically, high thermal conductors 83 penetrate through core insulating layer 50 in the thickness direction of insulating substrate 2, and are located between first insulating layer 51 and second insulating layer 52. Stated differently, high thermal conductors 83 in the present embodiment have the same shape as that of hollows 81. Each high thermal conductor 83 attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312 and enabling the user to use a desired function.

The distance between each high thermal conductor 83 and the lateral surface of first thermoelectric member 31 or second thermoelectric member 32 may be 1.7 mm or less. The distance between each high thermal conductor 83 and the lateral surface of first thermoelectric member 31 or second thermoelectric member 32 may be 0.05 mm or greater. With the distance in the foregoing range, the foregoing stress is harder to be generated. This configuration thus further reduces the breakage of first tubular members 301 and second tubular members 302.

Although not illustrated in the drawings, high thermal conductors 83 (thermal conduction portions) may penetrate through first surface 21 and second surface 22 in the thickness direction of insulating substrate 2. In this case, high thermal conductors 83 may penetrate through insulating substrate 2 in the thickness direction from insulating film 61 to thermally conductive layer 62. Note that high thermal conductors 83 have any shapes. Each high thermal conductor 83 penetrating through first surface 21 and second surface 22 attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312 and enabling the user to use a desired function.

Also note that high thermal conductor 83 may be in fluid communication with adjacent high thermal conductor 83. For example, high thermal conductor 83 between first thermoelectric member 31 and second thermoelectric member 32 of thermoelectric conversion unit 3a and high thermal conductor 83 between first thermoelectric member 31 of thermoelectric conversion unit 3a and second thermoelectric member 32 of thermoelectric conversion unit 3b are adjacent high thermal conductors 83. These two high thermal conductors 83 may be in fluid communication with each other.

The heat conductivity of high thermal conductors 83 may be between 1.0 W/m·K and 500 W/m·K, inclusive.

Each high thermal conductor 83 having the heat conductivity within the foregoing range more easily attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312.

High thermal conductors 83 may comprise Cu or Al, but the present disclosure is not limited to this. The heat conductivity of high thermal conductors 83 comprising Cu or Al is sufficiently high, and thus each high thermal conductor 83 more easily attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312.

### Embodiment 2

Before explaining Embodiment 2 according to the present disclosure, the problem of the conventional technology will be briefly described.

In the thermoelectric conversion substrate disclosed in WO2017/208950, heat transferred in the insulating substrate affects the function, life, etc. of the thermoelectric conversion units or an electronic device to be subjected to thermoelectric conversion. For example, heat, etc. generated from the electronic device, generated in the manufacturing process, or dissipated from the thermoelectric conversion units themselves causes a thermal expansion difference inside of the insulating substrate. The conventional technology thus has a problem that the thermoelectric conversion units are prone to breakage under such stress.

The present disclosure, which has been conceived in view of the foregoing problem, provides a thermoelectric conversion substrate and a thermoelectric conversion module that reduce the breakage of thermoelectric conversion units.

The following describes Embodiment 2 according to the present disclosure.

Each stress relaxation portion in Embodiment 1 is disposed between the first thermoelectric member and the second thermoelectric member, but the present disclosure is not limited this configuration. Each stress relaxation portion in Embodiment 2 is disposed electrically between a first thermoelectric member and a second thermoelectric member.

In the present embodiment, the structural components common to those of Embodiment 1 are assigned the same reference marks, and repetitive descriptions will be omitted.

The following describes Embodiment 2, using Examples 1 through 3.

### Example 1

Thermoelectric conversion module 101 according to Example 1 of Embodiment 2 is different from thermoelectric conversion module 10 according to Embodiment 1 in the following three points: insulating substrate 2c includes two second insulating layers 52; thermoelectric conversion unit-incorporating insulating layer 550 (hereinafter referred to also as unit-incorporating insulating layer 550) is disposed; and each stress relaxation portion is disposed electrically between first thermoelectric member 31 and second thermoelectric member 32.

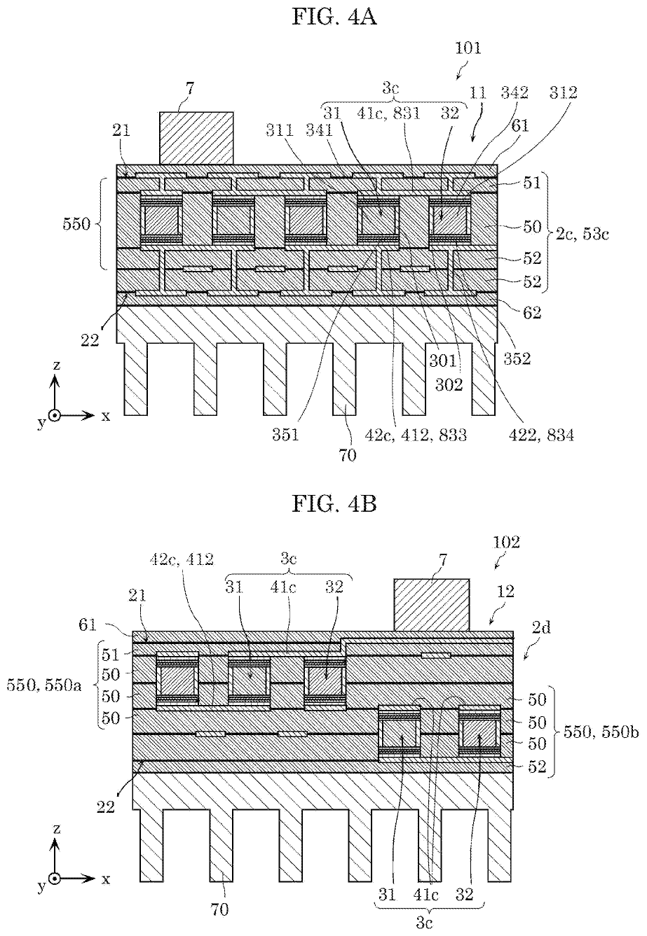

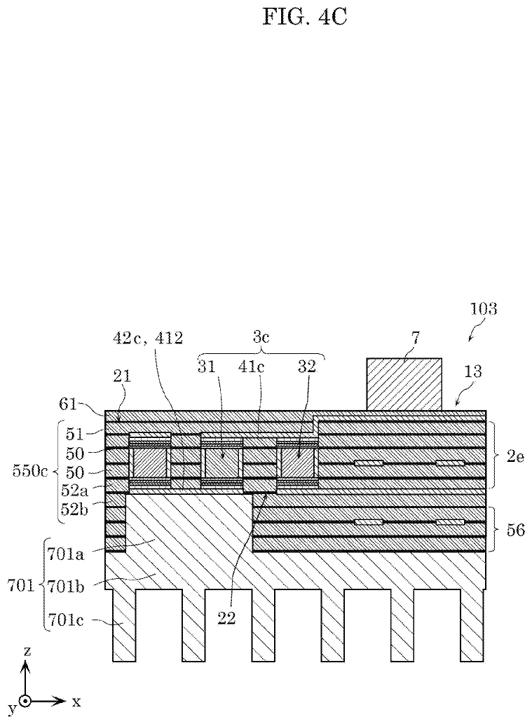

FIG. 4A is a schematic cross-sectional view of an example of thermoelectric conversion module 101 according to Example 1 of Embodiment 2.

Thermoelectric conversion module 101 includes thermoelectric conversion substrate 11, insulating film 61, electronic component 7, thermally conductive layer 62, and heatsink 70.

Thermoelectric conversion substrate 11 includes insulating substrate 2c, a plurality of thermoelectric conversion units 3c, and second electrode 42c. Thermoelectric conversion substrate 11 also includes unit-incorporating insulating layer 550 and stress relaxation portions.

Each of thermoelectric conversion units 3c includes first thermoelectric member 31, second thermoelectric member 32, and first electrode 41c. First thermoelectric member 31 includes first tubular member 301 and first semiconductor 311. First thermoelectric member 31 includes end portion 341 and end portion 351. Second thermoelectric member 32 includes second tubular member 302 and second semiconductor 312. Second thermoelectric member 32 includes end portion 342 and end portion 352.

Although not illustrated in the drawings, each first electrode 41c and second electrode 42c may include filled vias.

In the present embodiment, power source connection electrodes 412 and 422 are disposed on second surface 22 of insulating substrate 2c. Second electrode 42c may serve as a power source connection electrode as with second electrode 42 in Embodiment 1. Second electrode 42c is, for example, power source connection electrode 412.

Insulating substrate 2c includes first surface 21 on one side in a thickness direction of insulating substrate 2c and second surface 22 on the opposite side. Insulating substrate 2c includes core insulating layer 50, first insulating layer 51, and two second insulating layers 52. These two second insulating layers 52 are laminated. In this case, insulating substrate 2c is laminate 53c. As shown in FIG. 4A, two second insulating layers 52, core insulating layer 50, and first insulating layer 51 are laminated in insulating substrate 2c in stated order in a direction from heatsink 70 to electronic component 7 (toward the positive direction of the z axis).

In Example 1 of the present embodiment, second surface 22 is a surface of one of two second insulating layers 52 that is not in contact with core insulating layer 50.

Of the regions in laminate 53c in which thermoelectric conversion units 3c are embedded, a region that includes core insulating layer 50, one first insulating layer 51, and one second insulating layer 52 that is in contact with core insulating layer 50 is defined as unit-incorporating insulating layer 550. Stated differently, unit-incorporating insulating layer 550 includes core insulating layer 50 and insulating layers. In Example 1 of the present embodiment, such insulating layers included in unit-incorporating insulating layer 550 are first insulating layer 51 or second insulating layer 52 that is in contact with core insulating layer 50.

In Example 1 of the present embodiment, each stress relaxation portion is disposed electrically between first thermoelectric member 31 and second thermoelectric member 32. Note that each stress relaxation portion may be disposed electrically between the power source and at least one of first thermoelectric member 31 or second thermoelectric member 32.

As shown in FIG. 4A, the stress relaxation portions may be at least one of first electrodes 41c, second electrode 42c (power source connection electrode 412), or power source connection electrode 422. In Example 1 of the present embodiment, the stress relaxation portions are first electrodes 41c, second electrode 42c (power source connection electrode 412), and power source connection electrode 422. In the present embodiment, the heat conductivity of the stress relaxation portions may be, for example, higher than the heat conductivity of insulating substrate 2c.

The configuration including the stress relaxation portions as described above promotes the absorption or release of heat of insulating substrate 2c via the stress relaxation portions. For example, each stress relaxation portion attracts heat propagating around first thermoelectric member 31 or second thermoelectric member 32 and dissipates the heat to outside. This configuration prevents heat generated in electronic component 7 from causing a thermal expansion difference between core insulating layer 50, first insulating layer 51, or two second insulating layers 52 and first tubular members 301 or second tubular members 302. For this reason, stress is hard to be generated due to a thermal expansion difference. This reduces the breakage of first tubular members 301 and second tubular members 302. This consequently reduces the breakage of first semiconductors 311 and second semiconductors 312 incorporated in first tubular members 301 and second tubular members 302, thereby enabling the user to use a desired function.

Alternatively, the stress relaxation portions may be high thermal conductive materials through which heat is transferred into and out of a plurality of thermoelectric conversion units 3c. More specifically, first electrodes 41c, second electrode 42c (power source connection electrode 412), and power source connection electrode 422 are stress relaxation portions, as well as high thermal conductive material 831, high thermal conductive material 833, and high thermal conductive material 834.

Each of high thermal conductive material 831, high thermal conductive material 833, and high thermal conductive material 834 attracts heat propagating around first thermoelectric member 31 or second thermoelectric member 32 and dissipates the heat to outside. For this reason, the foregoing stress is hard to be generated. Consequently, this configuration reduces the breakage of first semiconductors 311 and second semiconductors 312, thereby enabling the user to use a desired function.

The heat conductivity of high thermal conductive material 831, high thermal conductive material 833, and high thermal conductive material 834 may be between 1.0 W/m·K and 500 W/m·K, inclusive, and may be higher than the heat conductivity of insulating substrate 2c.

With this, each of high thermal conductive material 831, high thermal conductive material 833, and high thermal conductive material 834 more easily attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312.

High thermal conductive material 831, high thermal conductive material 833, and high thermal conductive material 834 may comprise Cu or Al, but the present disclosure is not limited to this.

The heat conductivity of high thermal conductive material 831, high thermal conductive material 833, and high thermal conductive material 834 comprising Cu or Al is sufficiently high. As such, each of high thermal conductive material 831, high thermal conductive material 833, and high thermal conductive material 834 more easily attracts heat propagating around first thermoelectric member 31 and second thermoelectric member 32 and dissipates the heat to outside. This configuration makes the foregoing stress hard to be generated, thus reducing the breakage of first semiconductors 311 and second semiconductors 312.

### Example 2

Another example of Embodiment 2 is a configuration in which the thermoelectric conversion substrate includes a plurality of core insulating layers. In Example 2, the thermoelectric conversion substrate includes four core insulating layers. The thermoelectric conversion substrate also includes two thermoelectric conversion unit-incorporating insulating layers.

FIG. 4B is a schematic cross-sectional view of an example of thermoelectric conversion module 102 according to Example 2 of Embodiment 2.

Thermoelectric conversion module 102 includes thermoelectric conversion substrate 12, insulating film 61, electronic component 7, and heatsink 70.

Thermoelectric conversion substrate 12 includes insulating substrate 2d, second insulating layer 52, a plurality of thermoelectric conversion units 3c, and second electrode 42c. Thermoelectric conversion substrate 12 also includes a plurality of unit-incorporating insulating layers 550 and stress relaxation portions. More specifically, thermoelectric conversion substrate 12 includes two unit-incorporating insulating layers 550. For identification purposes, two unit-incorporating insulating layers 550 are also described distinctively as unit-incorporating insulating layer 550a and unit-incorporating insulating layer 550b.

Each of thermoelectric conversion units 3c includes first thermoelectric member 31, second thermoelectric member 32, and first electrode 41c.

Second electrode 42c is power source connection electrode 412 as with second electrode 42 in Embodiment 1.

Insulating substrate 2d includes first surface 21 and second surface 22 at both ends of insulating substrate 2d in the thickness direction. Insulating substrate 2d includes four core insulating layers 50 and first insulating layer 51. Four core insulating layers 50 are laminated. As shown in FIG. 4B, four core insulating layers 50 and first insulating layer 51 are laminated in insulating substrate 2d in stated order in a direction from heatsink 70 to electronic component 7 (toward the positive direction of the z axis).

In Example 2 of the present embodiment, unit-incorporating insulating layer 550a includes one first insulating layer 51 and three core insulating layers 50. Unit-incorporating insulating layer 550b includes three core insulating layers 50 and one second insulating layer 52. Note that unit-incorporating insulating layer 550a and unit-incorporating insulating layer 550b share two core insulating layers 50.

In Example 2 of the present embodiment, each stress relaxation portion is disposed electrically between first thermoelectric member 31 and second thermoelectric member 32 as with Example 1 of the present embodiment. Stated differently, the stress relaxation portions are first electrodes 41c and second electrode 42c (power source connection electrode 412). In the present embodiment, the heat conductivity of the stress relaxation portions may be, for example, higher than the heat conductivity of insulating substrate 2d.

The configuration including the stress relaxation portions as described above promotes the absorption or release of heat of insulating substrate 2d via the stress relaxation portions. For example, each stress relaxation portion attracts heat propagating around first thermoelectric member 31 or second thermoelectric member 32 and dissipates the heat to outside. For this reason, the foregoing stress is hard to be generated. Consequently, this configuration reduces the breakage of first semiconductors 311 and second semiconductors 312, thereby enabling the user to use a desired function.

With the configuration including a plurality of core insulating layers 50, it is possible to change the heat conductivity of each of core insulating layers 50 depending on the usage of thermoelectric conversion substrate 12.

In the configuration including a plurality of core insulating layers 50, as shown in FIG. 4B, not all first electrodes 41c need to be disposed on first surface 21. Similarly, not all second electrodes 42c need to be disposed on second surface 22.

Also, as in the present example, insulating substrate 2d may include two or more core insulating layers 50. It is easy, for example, to envisage an embodiment as shown in FIG. 4B from Embodiment 1. It is thus regarded as easy, in the case where insulating substrate 2d has a multilayer structure, to envisage the embodiment from Embodiment 1 without departing from such an envisagement.

### Example 3

Another example of Embodiment 2 is a configuration in which the thermoelectric conversion substrate includes a heatsink that is in contact with the thermoelectric conversion unit-incorporating insulating layer. In Example 3, the thermoelectric conversion module includes such heatsink.

FIG. 4C is a schematic cross-sectional view of an example of thermoelectric conversion module 103 according to Example 3 of Embodiment 2.

Thermoelectric conversion module 103 includes thermoelectric conversion substrate 13, insulating film 61, electronic component 7, and heatsink 701.

Thermoelectric conversion substrate 13 includes insulating substrate 2e, thermoelectric conversion units 3c, one second insulating layer 52 (second insulating layer 52b shown in FIG. 4C), and a plurality of third insulating layers 56. Thermoelectric conversion substrate 13 also includes unit-incorporating insulating layer 550c and stress relaxation portions.

Each thermoelectric conversion unit 3c includes first thermoelectric member 31, second thermoelectric member 32, and first electrode 41c.

Second electrode 42c is power source connection electrode 412 as with second electrode 42 in Embodiment 1.

Insulating substrate 2e includes first surface 21 on one side in the thickness direction of insulating substrate 2e and second surface 22 on the opposite side. Insulating substrate 2e includes one first insulating layer 51, two core insulating layers 50, and one second insulating layer 52 (second insulating layer 52a shown in FIG. 4C). As shown in FIG. 4C, second insulating layer 52a, two core insulating layers 50, and first insulating layer 51 are laminated in insulating substrate 2e in stated order in a direction from heatsink 701 to electronic component 7 (toward the positive direction of the z axis).

In Example 3 of the present embodiment, unit-incorporating insulating layer 550c includes two first insulating layers 51, two core insulating layers 50, and two second insulating layers 52 (second insulating layer 52a and second insulating layer 52b).

Each of third insulating layers 56 includes neither first thermoelectric member 31 nor second thermoelectric member 32. Each of third insulating layers 56 has a thickness of 200 μm or less. The heat conductivity of each of third insulating layers 56 is, for example, between 1.1 W/m·K and 1.6 W/m·K, inclusive, but the present disclosure is not limited to this. A plurality of third insulating layers 56 are laminated below insulating substrate 2e.

Heatsink 701 includes heatsink protruded portion 701a, heatsink flat portion 701b, and heatsink fin portion 701c.

Heatsink protruded portion 701a is a protruded region having a rectangular solid shape located above heatsink flat portion 701b. In a cross-sectional view, heatsink protruded portion 701a has a rectangular shape. Heatsink 701 is in contact with unit-incorporating insulating layer 550c. More specifically, heatsink protruded portion 701a is in contact with unit-incorporating insulating layer 550c in a manner that heatsink protruded portion 701a is embedded in second insulating layer 52b of unit-incorporating insulating layer 550c. Heatsink protruded portion 701a penetrates through a plurality of third insulating layers 56.

Heatsink flat portion 701b is in contact with one surface of one of third insulating layers 56 that are disposed below insulating substrate 2e.

Heatsink fin portion 701c includes projected portions to increase the surface area of heatsink 701.

Specific examples of the material of heatsink 701 include Cu and Al.

With the configuration including heatsink 701, heat propagating around first thermoelectric members 31 or second thermoelectric members 32 is attracted and dissipated to outside. For this reason, the foregoing stress is hard to be generated. Consequently, this configuration reduces the breakage of first semiconductors 311 and second semiconductors 312, thereby enabling the user to use a desired function.

In Example 3 of the present embodiment, each stress relaxation portion is disposed electrically between first thermoelectric member 31 and second thermoelectric member 32 as with Example 1 of the present embodiment. Stated differently, the stress relaxation portions are first electrodes 41c and second electrode 42c (power source connection electrode 412). In the present embodiment, the heat conductivity of the stress relaxation portions may be, for example, higher than the heat conductivity of insulating substrate 2e.

The configuration including the stress relaxation portions as described above promotes the absorption or release of heat of insulating substrate 2e via the stress relaxation portions. For example, each stress relaxation portion attracts heat propagating around first thermoelectric member 31 or second thermoelectric member 32 and dissipates the heat to outside. For this reason, the foregoing stress is hard to be generated. Consequently, this configuration reduces the breakage of first semiconductors 311 and second semiconductors 312, thereby enabling the user to use a desired function.

Also, a plurality of core insulating layers 50 may be disposed as shown in Embodiment 2. It is easy, for example, to envisage an embodiment as shown in FIG. 4C from Embodiment 1. It is thus regarded as easy, in the case where insulating substrate 2e has a multilayer structure, to envisage the embodiment from Embodiment 1 without departing from such an envisagement.

### Another Embodiment

The thermoelectric conversion substrate and others according to the present disclosure have been described above on the basis of the embodiments, but the present disclosure is not limited to these embodiments. The scope of the present disclosure also includes: an embodiment achieved by making various modifications and alterations to the embodiments that can be conceived by those skilled in the art without departing from the essence of the present disclosure; and another embodiment achieved by combining some of the structural components of the embodiments.

More specifically, the thermoelectric conversion substrate may include two or more stress relaxation portions, among a hollow, a protective material, and a thermal conduction portion, and/or a combination of two or more of these stress relaxation portions.

Also note that the foregoing embodiments allow for various modifications, replacements, additions, omissions, and so forth made thereto within the scope of the claims and its equivalent scope.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The thermoelectric conversion substrate and others according to the present disclosure are applicable for use as a thermoelectric conversion substrate and so forth that reduce the breakage of a thermoelectric conversion unit.

What is claimed is:

1. A thermoelectric conversion substrate, comprising:
an insulating substrate including a first surface on one side in a thickness direction of the insulating substrate and a second surface on an opposite side;
a plurality of thermoelectric conversion units, each including a first thermoelectric member, a second thermoelectric member, and a first electrode that is disposed on the first surface and electrically connects the first thermoelectric member and the second thermoelectric member; and
a second electrode disposed on the second surface,
wherein the insulating substrate includes at least one core insulating layer,
the first thermoelectric member and the second thermoelectric member are incorporated in the at least one core insulating layer,
the second electrode electrically connects the first thermoelectric member of one of the plurality of thermoelectric conversion units and the second thermoelectric member of another of the plurality of thermoelectric conversion units,
the plurality of thermoelectric conversion units are electrically connected in series in a manner that the first thermoelectric member and the second thermoelectric member are alternately arranged, and
a stress relaxation portion is disposed between the first thermoelectric member and the second thermoelectric member.

2. The thermoelectric conversion substrate according to claim 1,
wherein the stress relaxation portion is a hollow that is incorporated in the insulating substrate in the thickness direction of the insulating substrate.

3. The thermoelectric conversion substrate according to claim 1,
wherein the stress relaxation portion is a hollow that penetrates through the first surface and the second surface in the thickness direction of the insulating substrate.

4. The thermoelectric conversion substrate according to claim 2,
wherein a distance between the hollow and a lateral surface of at least one of the first thermoelectric member or the second thermoelectric member is between 0.05 mm and 1.7 mm, inclusive.

5. The thermoelectric conversion substrate according to claim 3,
wherein in a plan view of the hollow on the first surface or the second surface, an area of the hollow on a cooling side of each of the plurality of thermoelectric conversion units is smaller than an area of the hollow on a heat dissipation side of the thermoelectric conversion unit, the cooling side being one of the first surface and the second surface, the heat dissipation side being a remaining one of the first surface and the second surface.

6. The thermoelectric conversion substrate according to claim 5,
wherein a difference between the area of the hollow on the cooling side and the area of the hollow on the heat dissipation side is between 0.1 μm² and 0.1 mm², inclusive.

7. The thermoelectric conversion substrate according to claim 2,
wherein the hollow is adjacent to a lateral surface of the first thermoelectric member or the second thermoelectric member.

8. The thermoelectric conversion substrate according to claim 7,
wherein the hollow is located between the first thermoelectric member or the second thermoelectric member and part of the at least one core insulating layer disposed between the first thermoelectric member and the second thermoelectric member, and
a distance between the lateral surface of the first thermoelectric member or the second thermoelectric member and the part of the at least one core insulating layer is between 0.05 mm and 1.7 mm, inclusive.

9. The thermoelectric conversion substrate according to claim 8,
wherein a protruded portion is further provided that protrudes from the part of the at least one core insulating layer, and
the protruded portion is incorporated in the insulating substrate in the thickness direction of the insulating substrate, and contacts the lateral surface of the first thermoelectric member or the second thermoelectric member.

10. The thermoelectric conversion substrate according to claim 9,
wherein the protruded portion contacts the lateral surface of the first thermoelectric member or the second thermoelectric member in a manner that the protruded portion surrounds the lateral surface.

11. The thermoelectric conversion substrate according to claim 9,
wherein a length of the protruded portion in the thickness direction is between 0.1 mm and 1.2 mm, inclusive.

12. The thermoelectric conversion substrate according to claim 1,
wherein the stress relaxation portion is a protective material that is incorporated in the insulating substrate in the thickness direction of the insulating substrate.

13. The thermoelectric conversion substrate according to claim 1,
wherein the stress relaxation portion is a protective material that penetrates through the first surface and the second surface in the thickness direction of the insulating substrate.

14. The thermoelectric conversion substrate according to claim 12,
wherein a hardness of the protective material is lower than a hardness of the insulating substrate.

15. The thermoelectric conversion substrate according to claim 14,
wherein the protective material comprises silicone rubber.

16. The thermoelectric conversion substrate according to claim 15,
wherein under a condition that a bending elastic modulus of the insulating substrate is between 5 GPa and 30 GPa, inclusive, a Shore A hardness of the silicone rubber is between 30 and 80, inclusive.

17. The thermoelectric conversion substrate according to claim 15,
wherein a thickness of the silicone rubber is between 0.05 mm and 1.5 mm, inclusive.

18. The thermoelectric conversion substrate according to claim 12,
wherein at least one hollow is disposed between the protective material and at least one of the first surface or the second surface.

19. The thermoelectric conversion substrate according to claim 18,
wherein a length of the at least one hollow in the thickness direction is between 0.05 mm and 0.2 mm, inclusive, and
a length between the at least one hollow and a lateral surface of the first thermoelectric member or the second thermoelectric member is between 0.05 mm and 1.5 mm, inclusive.

20. The thermoelectric conversion substrate according to claim 1,
wherein the stress relaxation portion is a thermal conduction portion.

21. The thermoelectric conversion substrate according to claim 20,
wherein the thermal conduction portion is a high thermal conductor that penetrates through the first surface and the second surface in the thickness direction of the insulating substrate.

22. The thermoelectric conversion substrate according to claim 20,
wherein the thermal conduction portion is a high thermal conductor that is incorporated in the insulating substrate in the thickness direction.

23. The thermoelectric conversion substrate according to claim 21,
wherein a heat conductivity of the high thermal conductor is between 1.0 W/m·K and 500 W/m·K, inclusive.

24. The thermoelectric conversion substrate according to claim 21,
wherein the high thermal conductor comprises Cu or Al.

25. The thermoelectric conversion substrate according to claim 1,
wherein the insulating substrate includes a plurality of core insulating layers,
a thermoelectric conversion unit-incorporating insulating layer is disposed that includes an insulating layer and at least one of the plurality of core insulating layers, and
the stress relaxation portion is disposed electrically between the first thermoelectric member and the second thermoelectric member.

26. The thermoelectric conversion substrate according to claim 25,
wherein the stress relaxation portion is a high thermal conductive material through which heat is transferred into and out of the plurality of thermoelectric conversion units.

27. The thermoelectric conversion substrate according to claim 26,
wherein a heat conductivity of the high thermal conductive material is between 1.0 W/m·K and 500 W/m·K, inclusive.

28. The thermoelectric conversion substrate according to claim 26,
wherein the high thermal conductive material comprises Cu or Al.

29. A thermoelectric conversion module, comprising:
the thermoelectric conversion substrate according to claim 1;
an insulating film disposed on at least one of the first surface or the second surface of the insulating substrate of the thermoelectric conversion substrate; and
an electronic component disposed on the thermoelectric conversion substrate via the insulating film.
